(19) United States
(12) Patent Application Publication
(10) Pub. No.: US 2015/0168973 A1
(43) Pub. Date: Jun. 18, 2015

(54) STACKED CHIPS POWERED FROM SHARED VOLTAGE SOURCES

(71) Applicant: Hashfast LLC, San Francisco, CA (US)

(72) Inventor: Simon Barber, San Francisco, CA (US)

(21) Appl. No.: 14/572,535

(22) Filed: Dec. 16, 2014

Related U.S. Application Data
(60) Provisional application No. 61/917,828, filed on Dec. 18, 2013.

(51) Int. Cl. G05F 1/625; H01L 27/10; H01L 27/02

(52) U.S. Cl. CPC G05F 1/625; H01L 27/0248; H01L 27/10

(57) ABSTRACT

A system includes multiple integrated circuits (ICs), each with a high supply level input and a low supply level input. With respect to the topology of these power connections, the ICs are connected serially between a high power supply level and a low power supply level, so that the low supply level input connection of each IC in the series is connected to supply the high supply level input of the next IC in the series. The high supply level input of the first IC in the series is connected to a chassis supply voltage line, and the low supply level input of the last IC in the series is connected to a chassis return voltage line. The system may include matching of parts at manufacturing time, and/or using active control circuitry so that the voltage across each of the chips is maintained within a range of operational values.

### FIELD OF THE INVENTION

The present invention relates generally to the powering multiple integrated circuits from a source wherein some of the multiple integrated circuits' power inputs are coupled in series.

### BACKGROUND OF THE ART

To operate, an integrated circuit (“IC”) might be powered by a DC voltage applied between a source voltage input and a drain voltage input or ground. In the general case, there is a high supply level input and a low supply level input. In a specific case, such as for CMOS architecture, the source voltage input might be labelled “V_{SS}” and the drain voltage input might be labelled “V_{DD}”. Herein, the two power connections/pins/tabs/wires/etc. are referred to as “inputs” even though electrons flow into one of those inputs and out the other of those inputs. In most of the examples herein, the two power inputs are referred to as “high supply level input” and “low supply level input.”

Typically, the low supply level is at the same voltage as the ground plane, although other values (including negative voltages) can be used. Typically, the high supply level input and the low supply level input are such that the supply voltage (e.g., the difference between the high supply level input and the low supply level input) is sufficient to drive needed circuits within that integrated circuit. For example, some microprocessors require +5 V and GND (ground) inputs to operate, whereas others might be able to operate with a supply voltage of 3.3 V.

The typical integrated circuit that performs some processing of external inputs and/or outputs signals will have some requirements for such data/control inputs and/or outputs. For example, digital signals for inputs to the 5 V microprocessor mentioned above might range between a high signal value (often represented as a “1”) somewhat less than +5 V above GND and a low signal value somewhat above GND. This allows signals to be easily processed and used to switch transistors that make up the integrated circuit.

The minimum required supply voltage for integrated circuits has been going down. As a result, an electronics chassis, such as the motherboard, etc. of a desktop computer, might have a 12 V power supply and have integrated circuits (“ICs”) that only need 3.3 V power. One way to address the difference, which is wasteful of electrical power, is to use a passive network of components to step down the supply voltage from 12 V to 3.3 V. A less wasteful approach is to use a DC-DC converter that has a 12 V input and a 3.3 V output. Some power is lost in the conversion, but if the output current available for a given input current is higher, then not all of the power involved in the step-down is lost. However, higher currents require larger wires and traces to carry that current.

In an example chassis, such as a desktop computer, there might be one power supply that converts line/mains AC voltage (e.g., 110 V, 120 V, 240 V) to 12 V DC for distribution around the chassis and multiple DC-DC converters to convert the 12 V DC at one current level to 3.3 V DC at a higher current level, or an even lower voltage, such as 0.8 V DC. Because the lower voltages are delivered at higher currents (to move an equivalent amount of power), it is often preferable to have the DC-DC converters mounted close to the IC that will be using its power. This might require multiple DC-DC converters, which can add to the total cost of manufacture of a piece of equipment.

In the typical chassis, there can be multiple ICs, each coupled to the same ground and to the same supply voltage (from a common source or perhaps from a distributed plurality of DC-DC converters). Intercommunications between ICs that have the same high supply level and the same low supply level can be as simple as connecting outputs to inputs with circuits designed to output a voltage signal between the high supply level (or perhaps a little below that) and the low supply level (or perhaps a little above that) and designed to handle inputs in that same range.

Where more than one IC shares a power source, the power supplied to those ICs might be in parallel, wherein the high supply level inputs of each of those ICs are tied together and connected to a power supply line and wherein the low supply level inputs of each of those ICs are tied together and connected to ground (or some other low supply level source). In such a parallel arrangement, the current requirements from the supply are often the current requirements of one IC times the number of ICs. This can lead to requirements for circuit traces, wires, elements, etc. that are adapted to carry large currents.

In a system having multiple ICs that are designed to run with low supply voltages, it might make sense to run them all in parallel, such as when the system is battery-powered and the ICs require a supply voltage that is almost the battery voltage. While this might be convenient for systems powered by battery, can lead to additional power wastage when the supply level needs to be stepped down from a high voltage initial supply to a level suitable for used with the ICs.

### SUMMARY

A system, circuit board, enclosure that holds and interconnects a plurality of ICs (hereinafter “chassis”) provides for mounting and interconnects among the multiple IC chips. For at least some of the ICs, they have their power supply level inputs connected in series and, as a result, current from a power source will flow through one IC to power its operations and that when that current flows out of the low supply level input of one IC, it is applied to the high supply level input of the next IC. In this manner, the chassis provides for “stacks” of multiple ICs, wherein the same current (ignoring leakage) flows through the ICs (say from the top of the stack to the bottom of the stack) and the voltage from the power supply is divided (evenly, approximately so, or not in some cases) over the ICs in the stack. Different methods and structures can be used for handling interconnect, IOs and control signals, such as a clock signal and a reset signal. The ICs in a stack might communicate with signals that are level shifted, as ICs can be expected to have non-overlapping high/low signal voltages. The level shifting might be done using capacitors, level shifters and comparators, opto isolators or other techniques. The ICs can communicate and/or be programmed to coordinate their current use so that each ICs effective resistance on its power line stays the same (or approximately so) for each of the ICs in the stack, even as the current used for the stack goes up and down.

In some embodiments, for example, a line/mains voltage AC-DC converter might convert 110 VAC to 12 VDC and that 12 VDC is applied to a stack of fifteen ICs that each require an 0.8 V drop between their power and ground lines. In some embodiments, the ICs are protected from overload in the case where some of the ICs in a stack get to a state where they have might higher effective resistances relative to the other ICs in the stack. In one example, a Zener diode with a conducting voltage of 1.2 V to 1.5 V is connected across an IC's power lines. If this is done for each of the ICs in the stack, then if one IC starts pulling much less current than the other ICs in the stack (which would raise its supply voltage proportionately), the Zener diode for that one IC would shunt the current around the IC. Of course, the more current that is shunted through Zener diodes rather than being used for circuit operations such as computations, the less power-efficient the chassis becomes. A linear regulator may also be used to shunt excess voltage.

In some embodiments, an initial low current is drawn (by each of the ICs in the stack) and through coordination, they work together to take in more and more current to power up more of the IC, but do so in sync (or approximately so). This fine control of the effective load of a given IC (i.e., its effective resistance when maintaining a constant IC supply voltage drop) can be done in a number of ways. For example, an IC can skip a clock cycle to temporarily reduce its current usage, or where the IC has multiple circuits, it could slowly bring them up, in sync with the others.

Various aspects, advantages, features and embodiments of the present invention are included in the following description of exemplary examples thereof, which description should be taken in conjunction with the accompanying drawings. All patents, patent applications, articles, other publications, documents and things referenced herein are hereby incorporated herein by this reference in their entirety for all purposes. To the extent of any inconsistency or conflict in the definition or use of terms between any of the incorporated publications, documents or things and the present application, those of the present application shall prevail.

### BRIEF DESCRIPTION OF THE DRAWINGS

FIG. 1 is a block diagram of an exemplary embodiment for a stacked power connection arrangement of a multi-chip system.

FIG. 2 is a schematic diagram showing elements of FIG. 1 in greater detail.

FIG. 3 illustrates a more detailed view of an IC and its environs.

FIG. 4 illustrates capacitive coupling used to deal with communicating ICs having different supply ground levels.

FIG. 5 illustrates a chassis with branching stacks.

### DETAILED DESCRIPTION

As used herein, “chassis” refers to a system, circuit board, computational electronics, enclosure, etc. that holds and interconnects a plurality of ICs and provides for mounting and interconnects among the multiple ICs. As used herein, “integrated circuit” or “IC” refers to a circuit that is built upon a single die or multiple dies configured to be one integrated circuit. The circuit might be for performing analog operations or digital operations. Herein, a frequent example used is an IC that contains circuitry for performing digital computations, but the present invention finds application in other types of circuits as well. A digital IC might perform operations in sync with a clock signal, such as a clock generated external to the IC or internal to the IC. The IC typically has pins, tabs, contacts, etc., via which the chassis provides power to the IC and via which the IC takes in input signals and outputs output signals. By applying a voltage across a high supply level input of the IC and a low supply level input of the IC (e.g., the “PWR” and “GND” pins of some ICs), the circuits in the IC can draw supply current and operate. As used herein, “supply voltage” for an IC refers to the voltage difference between the high supply level input of the IC and the low supply level input of the IC. To simplify explanations herein, the voltage at the high supply level input will be assumed to be more positive than the voltage at the low supply level input, but these teachings can be applied to negative supply voltages and/or relative supply voltages. In a conventional circuit board or other chassis, all ICs might have their low supply level inputs connected to a ground plane via a low-resistance metal path as well as having their high supply level inputs connected in common to a power supply path (wire, trace, conductor, etc.).

In chassis described herein, ICs might not be connected in that manner and some

ICs can be “stacked”, wherein the plurality of stacked ICs have an order with the high supply level input of the first IC in the stack connected to a chassis supply voltage line (such as the V_{DD} line for CMOS ICs), the low supply level input of the first IC in the stack connected to the high supply level input of the second IC in the stack, and so on, with the low supply level input of the last IC in the stack connected to a chassis return voltage line (which may be a ground or other power supply return line as the case may be, such as the V_{SS} line for CMOS ICs). Note that while the term “stacked” is used herein to describe a plurality of ICs with power supply lines connected serially, the physical position of that plurality of ICs might not be such that they are aligned in a configuration resembling a stack. The chassis may include matching of parts at manufacturing time, and/or using active control circuitry so that the voltage across each of the ICs is maintained within a range of operational values. Of course, it should be understood that an identical or equivalent circuit would exist if the ordering were arbitrarily defined as counting first from the chassis return voltage line to last at the chassis source voltage line compared to a circuit wherein the ordering is defined as counting first from the chassis source voltage line to last at the chassis return voltage line.

As used herein, the “effective resistance” of an IC at any given snapshot in time is simply the IC's supply voltage at that snapshot in time divided by the amount of current flowing through the IC's supply level inputs at that snapshot in time. Under some conditions, it can be assumed that the current that flows into an IC via its high supply level input is identical to the current that flows out of the IC's low supply level input. In actual operation, a circuit might react so as to make that not be true. For example, a circuit element could be storing charge or discharging charge, or there could be a net flow of current among the IC's signal lines. Herein, the effects of charge buildup, discharge, and net current flow through input/output lines are assumed to be small relative to the power current and examples and description herein assumes that the supply current into an IC is the same as the supply current out of the IC and/or that the difference is small enough that it can be ignored.

Different power supply voltages and different IC supply voltages might be used for different stack configurations. For example, a 12 V power supply voltage might be used with a stack of four ICs that each requires an IC supply voltage of around 3 V. In another example, the power supply voltage is 12 V, each IC runs on 0.8 V and there are fifteen ICs in a stack. Of course, the alignment doesn't need to be exact and variances might be tolerated. Thus, a 12 V might still work with only fourteen 0.8 V ICs in a stack. In some cases, there might be as many as 100 or more ICs in a stack. Of course, a stack of one hundred 0.8 V ICs might require a power supply voltage of at least 80 V and so a chassis that supports 100-IC stacks would have to be rated to safely support such high voltages. Also, at some number of ICs per stack, coordination and overhead costs might exceed any benefits of stacking or only provide marginal benefits.

In some cases where cost and construction are a consideration, the power supply voltage is not to exceed 24 V, 48 V or some other maximum permissible voltage for a given construction. Certification and inspection requirements are often easier for lower maximum voltage chassis, so in some cases it might be preferable to have six stacks of fifteen 0.8 V ICs rather than one stack of ninety 0.8 V ICs, as the former would require a max supply voltage of 12 V whereas the latter would require a max supply voltage of 72 V. As an additional flexibility, currents through ICs do not necessarily have to be matched across stacks.

Although more generally applicable, this arrangement can be particularly useful for systems employing large numbers of ICs used concurrently in power-intensive computational operations, such as complex mathematical computations.

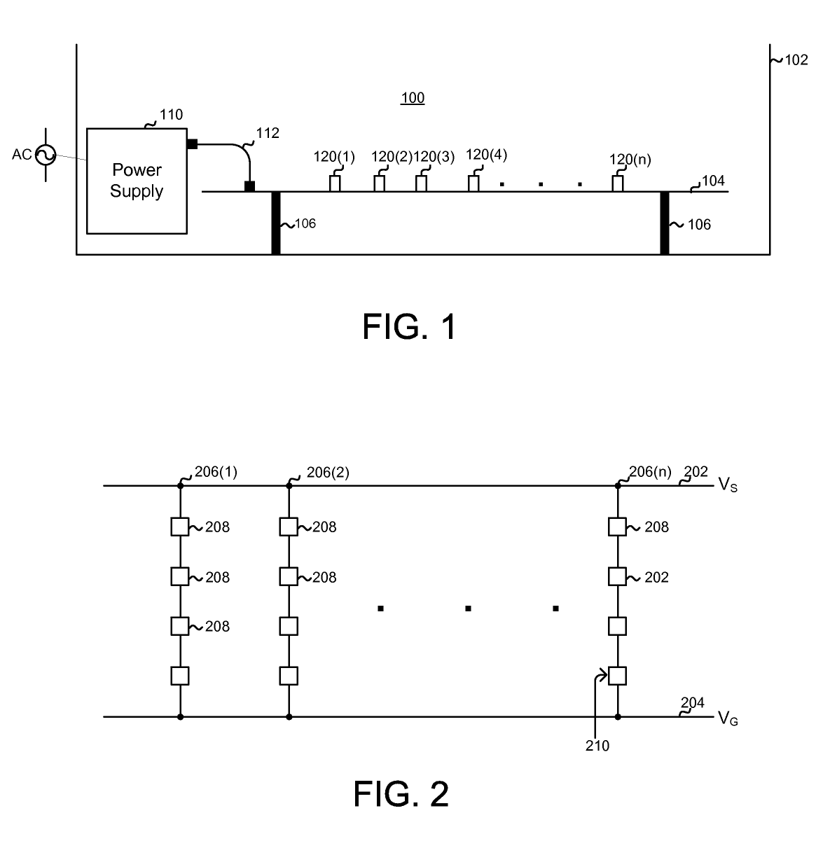

FIG. 1 is a block diagram of an exemplary embodiment for a stacked power connection arrangement of a multi-chip system used to illustrate various aspects. In FIG. 1, a chassis 100 comprises an enclosure 102, a printed circuit board (“PCB”) 104 mounted to enclosure 102 by possibly nonconducting mounts 106. Enclosure 102 also encloses a power supply 110 that takes in a line/mains voltage and outputs another voltage that is supplied to PCB 104 via wire harness 112. ICs 106(1)-(m) are mounted into or onto PCB 104 and PCB 104 might provide the necessary traces for supply lines and input/output lines for ICs 106(1)-(m). Various other mechanical and electrical elements (not shown) might be present as well. For example, ICs 106 might be thermally coupled to a heat sink.

FIG. 2 is a schematic diagram showing elements of FIG. 1 in greater detail. In particular, shown there is a chassis supply voltage line (V_{S}) 202, a chassis supply voltage return (V_{G}) 204 (which might or might not be tied to a ground plane, but in many examples here it is). Also shown are several stacks 206(1)-(n) of ICs 208. For simplicity, input/output lines of ICs 206 and many other elements are not shown. Note that stack 206(n) is illustrated with five ICs 210 and other stacks have four ICs. It is not required that all stacks have the same number of ICs, but that might be convenient and simple for some constructions.

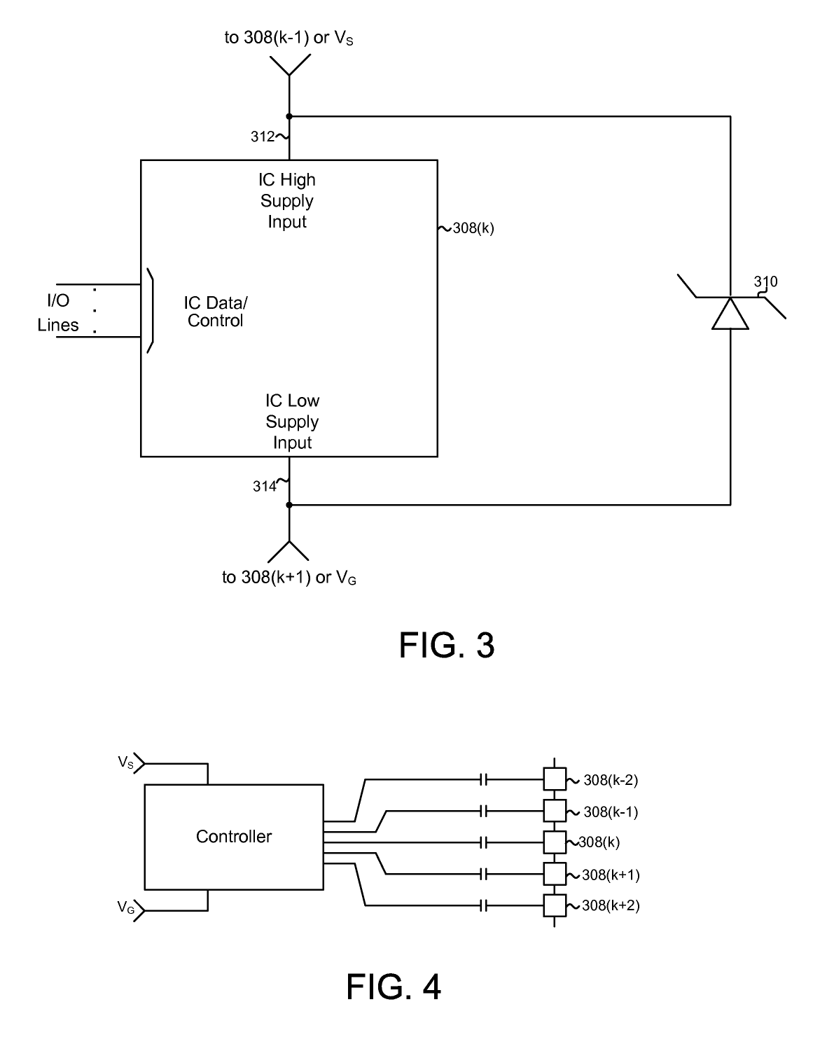

FIG. 3 illustrates a more detailed view of a schematic showing on IC 308(k). The high supply level input to IC 308(k) is coupled to the low supply level input to IC 308(k−1) (or to V_{S} in the case of k=1). The low supply level input pin for IC 308(k) is coupled to the high supply level input to IC 308(k+1) (or to V_{G} in the case where there are k ICs in the stack). A Zener diode 310 is provided across the supply level inputs of IC 308(k). The Zener diode's breakdown voltage might be selected so that it conducts before excessive voltage is applied across IC 308(k) but doesn't conduct during normal operation. When Zener diode 310 does break down, it would clamp the voltage across IC 308(k). It may be that IC 308(k) would continue to operate, powered at the breakdown voltage, but some power would likely be wasted when Zener diode 310 does conduct. As explained herein, if the variations in effective load among ICs in a stack are kept small enough, a Zener diode would only need to dissipate a small amount of power even when it does conduct. As an example, where an IC runs on 0.8 V power and has gate logic that can momentarily survive voltages up to 2.3 V before the gate oxide breaks down and the IC is permanently damaged, a Zener diode with a breakdown voltage of 1.2 V or 1.5 V, or other voltage shunt might be used to protect that IC.

In FIG. 3, IC 308(k) is shown having a plurality of input/output data/command lines. These might be used as a data bus, clock input, signal output, trigger inputs/outputs, or other purposes. Preferably the input voltages to IC 308(k) stay between the IC's high supply level input voltage (at node 312) and the IC's low supply level input voltage (at node 314). Of course, for different ICs in a stack, those voltages are different.

### Input/Output Signalling

Communications between different ICs in a stack, or between ICs more generally that have different high/low supply levels, level shifting or DC isolation might be used. For digital signals, for example, they can be level shifted using level shifters and/or comparators. DC isolation might be achieved using capacitive coupling, as shown in FIG. 4. Level shifting may work well if there are not too many ICs in a stack, such as where the supply voltage (V_{S}−V_{G}) is 3 V or 12 V and each ICs runs on 0.6 V or 0.8 V IC supply.

Other ways to deal with the relative shift of input rails for various ICs in a stack might include the use of isolation transformers, opto isolators or the like.

### Effective Load Management

If all of the ICs in a stack, powered in series, have the same effective resistance at any given time, they should see the same IC supply voltage. There are a number of ways to control effective load of an IC. If an IC performs computations faster and thus draws more current than otherwise, its effective resistance is said to drop. Thus, methods of controlling and/or maintaining a desired effective resistance can be equivalent to methods of controlling and/or maintaining a desired current consumption.

Supply current used by a circuit can vary based on how much switching is going on. So, for a circuit that doesn't assume a certain clock rate, the clock rate could be lowered to reduce the supply current used or raised to increase the supply current used. Also, clock cycles might just be skipped. This works well with fully static processors (i.e., processors that do not assume a certain clock rate or require a certain minimum clock rate for proper operation of the processor or associated memory).

Another way to alter the supply current used is by changing the operations performed. For example, a simple computing operation might cause less supply current to be drawn relative to a more complex computing operation.

Coordination between ICs might be done by signalling (e.g., a central controller indicating to each IC what they should be targetting, sent via point-to-point unicast or broadcast) or by programming (e.g., each IC, from when it first powers up, follows a predictable current draw over time, in sync with the other ICs). In another variation, the ICs do not need to communicate with each other, but just monitor their own IC power supply voltage, slowing down when its IC power supply voltage gets too low and speeding up when its IC power supply voltage gets too high. If each IC is left to decide on its own whether to raise or lower its effective resistance to maintain a target IC power supply voltage (e.g., by altering the clock speed, the number of cores used, or other methods of controlling effective resistance), a feedback mechanism might be needed to avoid all the ICs in a stack from fighting to increase its IC power supply voltage by increasing its effective resistance and losing the battle to other ICs in the stack, or fighting to decrease its IC power supply voltage by decreasing its effective resistance and losing the battle to other ICs in the stack.

Yet another way to alter the supply current used by each IC is where each IC is a multicore processor where individual cores can be turned on or off. In an example chassis, there are some number of ICs in a stack (say, for example, twelve) and each ICs has multiple cores (say, for example, four, fifty, or one hundred cores per IC). By varying the number of cores that are active, an IC can control its effective resistance.

### Ramping Up

Upon initial startup, each IC might be configured to start only one core. With one core running on each IC, they can communicate and coordinate. An IC might also be aware of its effective resistance relative to the others ICs in its stack. By programmed agreement, if each IC agrees that its one core is operating within a tolerance, it might fire up another core.

While this would be expected to increase the supply current, if all of the ICs fire up at around the same time, their effective resistance drops all at the same time, and the supply voltage across each IC remains relatively constant. In this manner, the ICs can coordinate to get up to each running all of their one hundred cores. At full speed operation, variations in effective resistance can be cancelled out by shutting down a core, changing a clock speed, or other techniques to keep a balance. An IC might comprise a single die or multiple dies.

Ramping up might also be done in other manners, such as slowly ramping up a clock rate. For example, suppose an IC is designed to run at a full speed of 700 MHz (7×10⁸ clock cycles/second). Suppose further that the IC has a static design in that proper operation does not require a minimum clock speed. The stack could be configured, by programming or otherwise, such that upon the initial application of power, the clocks of the ICs all run at 10 MHz. The ICs might then coordinate among themselves, determine that a faster clock speed is workable, and then all switch to a 20 MHz clock around the same time. From there, the ICs could ramp up, in sync, to full speed operation.

Of course, if a processor in the stack that is operating is able to detect departure from a norm, the adding of cores could be paused. In some embodiments, dummy work may be performed by some ICs in the stack simply to maintain their effective load the same as others in the stack, or simply to control the rate at which the stack as a whole increases or decreases its power consumption.

In many embodiments, control circuitry and communications infrastructure is provided so that each chip in the series can coordinate its own power consumption so that even as the overall current consumed may vary over time, the effective load presented by each chip is matched or coordinated such that each individual chip's power supply voltage is constant or stays within a limited range notwithstanding the fact that the series of chips are powered by a voltage source. Decoupling across individual ICs in the stack with capacitors and inductors may be used to smooth out high frequency (short temporal) variations in effective load, in which case effective load balancing might only be needed for medium and low frequency variations.

### SPECIFIC EXAMPLE

In a very specific example, about 20 ICs are used in a stack, wherein each IC comprises four dies and each of the dies contains 100 processor cores. At initialization, each IC (or each die) operates only one core and draws less than 100 milliamps in its “cold” state. Once those cores are operating, they communicate and/or coordinate as needed to bring up additional cores, stepping up one or a few cores at a time. At full operation, the stack might comprise 20 ICs each with 400 total processor cores operating and drawing as much as 400 amps at 0.8 V.

### Other Variations

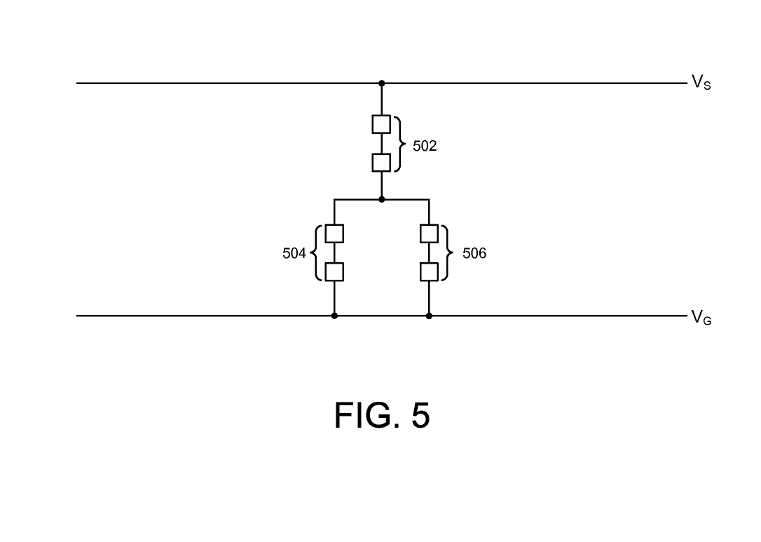

ICs can be configured, as explained above, in a single stack or in multiple stacks. If an application calls for it, a chassis might have “branching stacks” wherein current might split or join at a branch of a stacked chain of ICs, as illustrated in FIG. 5. As shown there, current flows through two ICs (branch 502) and then splits over two pairs of ICs (branches 504, 506). In such cases, current balancing might be more complex.

A chassis with stacks of ICs might be used to perform complex computations or other operations that are amenable to parallel computation. In other words, where a complex computation can be parsed into t threads, each thread might be assigned to one oft ICs in a stack. Where the computation performed by each IC is commensurate, such as in Single Instruction, Multiple Data applications (“SIMD”), load balancing might be easier.

A separate controller circuit might be used to tell each IC whether to raise or lower its effective load, or that functionality could be built into the ICs.

A stack of perfectly identical ICs performing exactly the same number and type of computational steps might well be expected to draw exactly the same power among each IC and therefore maintain a constant IC supply voltage even as the current varies. In practice, such tight matching might require a cost-prohibitive manufacturing process to match dies, due to normal variations in silicon performance. Noting that matching across stacks is not as important as current matching within a stack, perhaps chassis can be constructed wherein each IC is tested before placement and ICs are grouped in stacks such that each IC in a given stack has a similar performance and ICs with greatly dissimilar performances are assigned to different stacks. In this manner, ICs can be more closely matched without requiring that all ICs match all other ICs.

In some embodiments, a current supply is used with, or in place of a voltage supply.

In some embodiments, all of the ICs of a given stack are of the same type, whereas in other embodiments, the stack is configured taking into account that different ICs are present in the stack.

In some variations, the IC supply voltage need not be so tightly controlled and can vary over a larger range of IC supply voltages without unwanted effects. In such variations, proportionally less control over the IC's effective load would be required.

Further embodiments can be envisioned to one of ordinary skill in the art after reading this disclosure. In other embodiments, combinations or sub-combinations of the above disclosed invention can be advantageously made. The example arrangements of components are shown for purposes of illustration and it should be understood that combinations, additions, re-arrangements, and the like are contemplated in alternative embodiments of the present invention. Thus, while the invention has been described with respect to exemplary embodiments, one skilled in the art will recognize that numerous modifications are possible.

For example, the processes described herein may be implemented using hardware components, software components, and/or any combination thereof. The specification and drawings are, accordingly, to be regarded in an illustrative rather than a restrictive sense. It will, however, be evident that various modifications and changes may be made thereunto without departing from the broader spirit and scope of the invention as set forth in the claims and that the invention is intended to cover all modifications and equivalents within the scope of the following claims.

Although the various aspects of the present invention have been described with respect to certain embodiments, it is understood that the invention is entitled to protection within the full scope of the appended claims.

What is claimed is:

1. A system comprising:
a plurality of integrated circuits, having an ordering and thus forming at least a logical stack, each integrated circuit comprising:
(a) a high power supply level input connection; and
(b) a low power supply level input connection, wherein current flowing between the high power supply level input and the low power supply level input provides power to operate the integrated circuit; and
power interconnections between power supply level inputs of stack, wherein the integrated circuit that is first in the ordering has its high power supply level input connected to a chassis supply voltage line and each of the other integrated circuits in the stack have their high power supply level input connected to the low power supply level input of an integrated circuit that precedes it, and wherein the integrated circuit that is last in the ordering has its low power supply level input connected to a chassis return voltage line and each of the other integrated circuits in the stack have their low power supply level input connected to the high power supply level input of an integrated circuit that succeeds it.

2. The system of claim 1, wherein the plurality of integrated circuits are configured into a plurality of stacks, with integrated circuits having manufacturing variations are grouped into the stacks of the plurality of stacks based on matching manufacturing similarities within stacks.

3. The system of claim 1, further comprising active control circuitry to control voltage across each of the integrated circuits to maintain each integrated circuit's supply voltage within a range of operational values, an integrated circuit's supply voltage being a difference between the integrated circuit's high power supply level input and the integrated circuit's low power supply level input.

4. The system of claim 1, further comprising input/output isolators or level shifters that provide for different integrated circuits in the series having supply rails.

5. The system of claim 1, further comprising control circuitry and communications infrastructure controlling each integrated circuit's own power consumption so that even as the overall current consumed may vary over time, the power consumption of each integrated circuit is matched or coordinated such that each individual integrated circuit's supply voltage is constant or stays within a range of operational values.

6. The system of claim 5, wherein the control circuitry includes logic to alter an effective load of an integrated circuit to more closely match effective loads of other integrated circuits sharing a stack.

7. The system of claim 6, wherein the logic to alter the effective load comprises logic to cause integrated circuits with effective loads that are too low to perform additional dummy work to increase effective load.

8. The system of claim 6, wherein the logic to alter the effective load comprises logic to cause integrated circuits with effective loads that are too high to perform less work to decrease effective load.

9. The system of claim 8, wherein the logic to cause integrated circuits with effective loads that are too high to perform less work to decrease effective load comprises logic to skip clock cycles to reduce an amount of work done per unit time.

10. The system of claim 1, further comprising circuit decoupling for smoothing out high frequency variations in effective load.

11. The system of claim 10, wherein the circuit decoupling comprises capacitors and inductors coupled in series and/or parallel with the integrated circuits to smooth out the high frequency variations in effective load.

12. The system of claim 1, further comprising shunts for shunting excess transient voltage around one or more integrated circuit.

13. The system of claim 12, wherein the shunts comprise Zener diodes.

14. The system of claim 12, wherein the shunts comprise linear regulators.
